(19) United States
(12) Patent Application Publication
(10) Pub. No.: US 2026/0356224 A1
(43) Pub. Date: Nov. 12, 2026

(54) COOLING SYSTEM OF CHARGING SYSTEM AND CONTROL METHOD FOR COOLING SYSTEM

(71) Applicant: GUOCHUANG INNOVATION CENTER OF MOBILE ENERGY (JIANGSU) CO., LTD., Jiangsu (CN)

(72) Inventors: Hsien-Yi Tsai, Jiangsu (CN); Aiwen Peng, Jiangsu (CN); Kaiyi Sheng, Jiangsu (CN); Tingzhan Wang, Jiangsu (CN)

(73) Assignee: GUOCHUANG INNOVATION CENTER OF MOBILE ENERGY (JIANGSU) CO., LTD., Jiangsu (CN)

(21) Appl. No.: 19/125,293

(22) PCT Filed: Nov. 28, 2023
(86) PCT No.: PCT/CN2023/134577

§ 371 Date: Apr. 28, 2025

(30) Foreign Application Priority Data
Dec. 8, 2022 (CN) 202211569082.2

(51) Int. Cl. B60L 53/302; H05K 7/20

(52) U.S. Cl. CPC B60L 53/302; H05K 7/20309; H05K 7/20318; H05K 7/20327; H05K 7/20354; H05K 7/20381

(57) ABSTRACT

A cooling system of a charging system and a control method for the cooling system. The cooling system comprises: a vapor compression cooling unit, comprising: a compressor, a condenser, a throttling element, and an evaporator which are sequentially connected by means of a vapor compression pipe; a forced convection cooling unit, comprising: a liquid cooling plate, a heat exchanger, the evaporator, and a water pump which are connected by means of a cooling pipe, the liquid cooling plate being tightly attached to a power module of the charging system; and a fan arranged directly opposite to the heat exchanger and the condenser. The evaporator comprises a first flow channel and a second flow channel. The evaporator is used for evaporating a refrigerant flowing out of the condenser and performing convective heat exchange on a cooling liquid in the second flow channel and the refrigerant of the first flow channel.

### TECHNICAL FIELD

The invention relates to the field of electrical technology, specifically relates to a charging system for electric vehicles and a control method of the charging system for electric vehicles.

### DESCRIPTION OF RELATED ART

At present, the charging time of high-power charging systems such as new energy vehicles is relatively long. In order to ensure that the power modules of the charging system do not overheat during the charging process, the charging system needs to be cooled.

At present, most of the cooling methods for charging equipment are air-cooled, but the cooling efficiency of this approach is relatively low, and the cooling effect cannot be guaranteed.

In the related art, refrigerant is used for cooling the charging system. Although cooling efficiency may be improved through this approach, higher operating costs are needed, and the use of a single refrigerant for cooling is not environmentally friendly enough.

### SUMMARY

To solve the above technical problems, the first aspect of the invention provides a cooling system of an electric charging system.

The second aspect of the invention provides a control method for the cooling system of the charging system.

The technical solutions adopted by the invention are provided as follows.

The first aspect of the embodiments of the invention provides a cooling system of a charging system, including: a vapor compression cooling unit, the vapor compression cooling unit including: a compressor, a condenser, a throttling element, and an evaporator which are sequentially connected by means of a vapor compression pipe, where the vapor compression cooling unit uses a refrigerant for circulation; a forced convection cooling unit, the forced convection cooling unit including: a liquid cooling plate, a heat exchanger, the evaporator, and a water pump which are connected by means of a cooling pipe, where the forced convection cooling unit uses a cooling liquid for circulation, and the liquid cooling plate is tightly attached to a power module of the charging system, where the condenser of the vapor compression cooling unit is arranged close to the heat exchanger of the vapor compression cooling unit, the vapor compression cooling unit and the forced convection cooling unit further include: a fan, the fan is arranged directly opposite to the heat exchanger and the condenser, the fan is used for air cooling the condenser and the heat exchanger, the vapor compression cooling unit and the forced convection cooling unit share one evaporator, the evaporator includes a first flow channel and a second flow channel, the vapor compression pipe communicates with the first flow channel, the cooling pipe communicates with the second flow channel, and the evaporator is used for evaporating a refrigerant flowing out from the condenser to perform convective heat exchange on the cooling liquid in the second flow channel and the refrigerant in the first flow channel.

The cooling system of the charging system of the invention also has the following additional technical features:

According to an embodiment of the invention, in the forced convection cooling unit, an inlet of the heat exchanger is connected to an outlet of the liquid cooling plate, an outlet of the heat exchanger is connected to an inlet of the second flow channel of the evaporator, and an outlet of the second flow channel of the evaporator is connected to an inlet of the liquid cooling plate by means of the water pump.

According to an embodiment of the invention, in the forced convection cooling unit, the second flow channel is also connected to the outlet of the heat exchanger through an electric regulating valve.

According to an embodiment of the invention, in the forced convection cooling unit, an outlet of the liquid cooling plate is connected to an inlet of the second flow channel of the evaporator through a first one-way valve. An outlet of the second flow channel of the evaporator is connected to an inlet of the liquid cooling plate by means of the water pump, and the outlet of the second flow channel of the evaporator is connected to an inlet of the heat exchanger. An outlet of the heat exchanger is connected to the inlet of the second flow channel of the evaporator by means of a second one-way valve.

According to an embodiment of the invention, the vapor compression pipe includes a copper tube.

The second aspect of the embodiments of the invention provides a control method for the cooling system of the charging system according to the first aspect of the embodiments of the invention, and the control method includes the following steps: A temperature of the power module of the charging system is obtained, and when the temperature of the power module reaches a starting temperature Tsta, the cooling system is controlled to start. An ambient temperature Tamb is obtained, and a mode selection temperature difference ΔT is obtained according to the starting temperature Tsta and the ambient temperature Tamb, where ΔT=Tamb−Tsta. The selection temperature difference ΔT is determined, where if the selection temperature difference ΔT is greater than a first set temperature K1, the forced convection cooling unit is controlled to start. If the selection temperature difference ΔT is less than or equal to the first set temperature K1 and greater than or equal to a second set temperature K2, first the forced convection cooling unit is controlled to start, a target temperature difference ΔTt is continuously detected after a first predetermined time, and if the target temperature difference ΔTt is greater than a third set temperature K3, the vapor compression cooling unit is controlled to start, where K1>K2, ΔTt=Tout-Ttar, Tout is an outlet liquid temperature of the liquid cooling plate, and Ttar is a target outlet liquid temperature of the liquid cooling plate. If the selection temperature difference ΔT is less than the second set temperature K2, the vapor compression cooling unit is controlled to start, or the vapor compression cooling unit and the forced convection cooling unit are controlled to start simultaneously.

The control method for the cooling system of the charging system of the invention also has the following additional technical features:

According to an embodiment of the invention, the method further includes the following steps. After the forced convection cooling unit starts, a water pump flow rate and a fan rotation speed are adjusted according to a value and a trend of the target temperature difference ΔTt. After the vapor compression cooling unit starts, a frequency of the compressor is adjusted according to the value and the trend of the target temperature difference ΔTt, and the water pump flow rate and fan rotation speed are adjusted simultaneously.

Beneficial effects provided by the invention include the following.

The invention provides a liquid cooling approach for charging piles. The cooling system is implemented in a combined form of forced convection and vapor compression, and the cooling liquid undergoes convective heat exchange and cooling in the evaporator by means of the forced convection cooling unit and the vapor compression cooling unit, so the energy cascade principle is utilized to the maximum extent, the effect of high-grade energy is fully utilized, the heat exchange efficiency is improved, and the costs are reduced.

Through the phase change refrigeration mode of vapor compression, the cooling liquid temperature is set to a lower temperature according to needs, so heat exchange efficiency is improved, and the heat dissipation needs of high-power charging are satisfied.

The cooling system and the charging system only need to be connected through pipe connectors, so production, installation, and later maintenance are easily performed, the high protective nature of the charging pile is ensured, contamination of the power module by polluted air from the outside is avoided, and the service life of the power module is thus prolonged.

The vapor compression pipe and the cooling pipe are mutually independent with high reliability.

The usage rate of the vapor compression unit is reduced in a hybrid cooling system, so damage to the environment is lowered, and it is more environmentally friendly.

The refrigerant flow of the cooling system is infinitely adjusted according to the temperature changes of the detection temperature point of the charging system, so the operating condition changes are responded quickly and energy-saving is thus achieved.

### DESCRIPTION OF THE DRAWINGS

FIG. 1 is a structural schematic view of a cooling system of a charging system according to a first embodiment of the invention.

FIG. 2 is a structural schematic view of the cooling system of the charging system according to a second embodiment of the invention.

FIG. 3 is a structural schematic view of the cooling system of the charging system according to a third embodiment of the invention.

FIG. 4 is a structural schematic view of the cooling system of the charging system according to a fourth embodiment of the invention.

FIG. 5 is a flow chart of a control method for the cooling system of the charging system according to an embodiment of the invention.

### SPECIFIC EMBODIMENTS

Description will now be made in detail to clearly and completely present preferred embodiments of the invention, examples of which are illustrated in the accompanying drawings. Nevertheless, the disclosed embodiments are merely part of the embodiments of the invention, not all the embodiments. Based on the embodiments of the invention, all other embodiments obtained by a person having ordinary skill in the art without making any inventive effort fall within the scope that the invention seeks to protect.

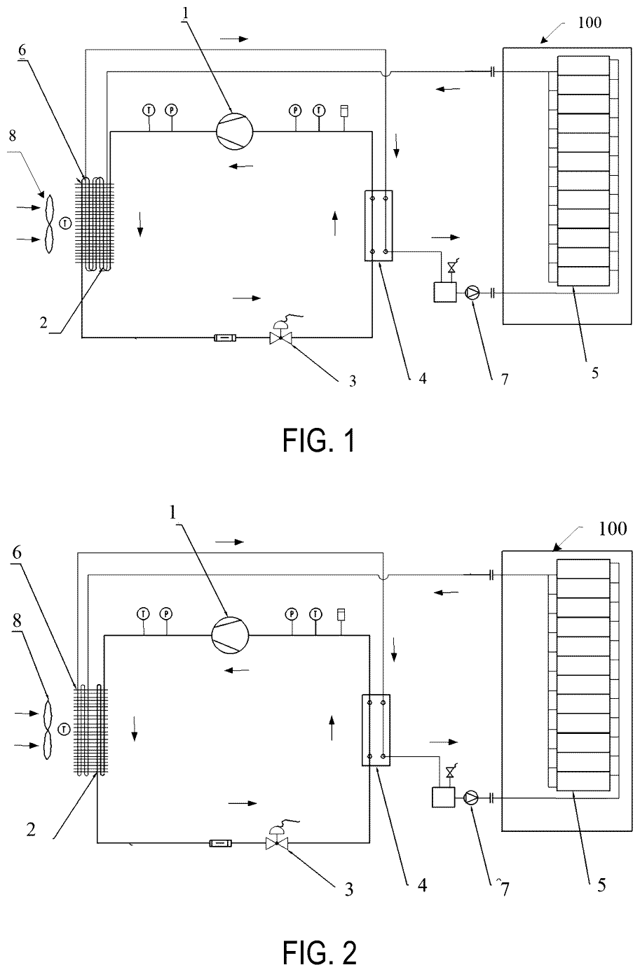

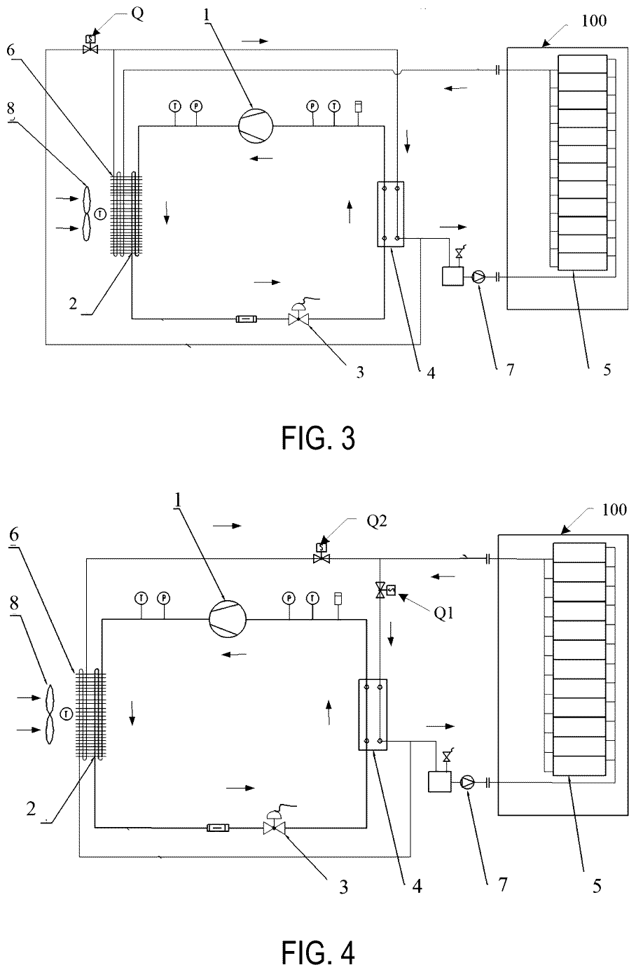

FIG. 1 is a structural schematic view of a cooling system of a charging system according to a first embodiment of the invention. FIG. 2 is a structural schematic view of the cooling system of the charging system according to a second embodiment of the invention. FIG. 3 is a structural schematic view of the cooling system of the charging system according to a third embodiment of the invention. FIG. 4 is a structural schematic view of the cooling system of the charging system according to a fourth embodiment of the invention. As shown in FIG. 1 to FIG. 4, the charging system includes: a vapor compression cooling unit and a forced convection cooling unit.

Herein, the vapor compression cooling unit includes: a compressor 1, a condenser 2, a throttling element 3, and an evaporator 4 which are sequentially connected by means of a vapor compression pipe as well as various sensors (P and T in FIG. 1 to FIG. 4) and refrigeration accessories, and the vapor compression cooling unit uses a refrigerant (coolant) for circulation. The forced convection cooling unit includes: a liquid cooling plate 5, a heat exchanger 6, the evaporator 4, and a water pump 7 which are connected by means of a cooling pipe, the forced convection cooling unit uses a cooling liquid (e.g., water) for circulation, and the liquid cooling plate 5 is tightly attached to a power module 100 of the charging system.

The condenser 2 of the vapor compression cooling unit is arranged close to the heat exchanger 6 of the vapor compression cooling unit, and the vapor compression cooling unit and the forced convection cooling unit further include: a fan 8. The fan 8 is arranged directly opposite to the heat exchanger 6 and the condenser 2, and the fan 8 is used for air cooling the condenser 2 and the heat exchanger 6. The vapor compression cooling unit and the forced convection cooling unit share one evaporator 4. The evaporator 4 includes a first flow channel and a second flow channel. The vapor compression pipe communicates with the first flow channel, and the cooling pipe communicates with the second flow channel. The evaporator 4 is used for evaporating a refrigerant flowing out from the condenser 2 to perform convective heat exchange on the cooling liquid in the second flow channel and the refrigerant in the first flow channel.

The vapor compression pipe may also include a copper tube.

To be specific, as shown in FIG. 1 to FIG. 4, the heat exchanger of the forced convection cooling unit and the condenser of the vapor compression may be integrally formed, may be separately assembled, and may be combined together in various structures such as cross, staggered, and one in front and one behind. FIG. 1 illustrates one of the cross-integrated combination modes, where the heat exchanger 6 and the condenser 2 are integrally formed in a crossed combination, and FIG. 2 illustrates one of the separate assembly modes.

A cooling approach of a charging pile system of the invention is liquid cooling heat dissipation. The power module 100 is tightly attached to the liquid cooling plate 5. The liquid cooling plate 5 is designed with an inlet and an outlet, and the liquid cooling plate 5 has penetrating micro channels inside, which carry away the heat of the power module 100 through the inflowing low-temperature cooling liquid.

The working process of the vapor compression cooling unit is: a low-pressure gaseous refrigerant is sucked into the compressor 1 and compressed into a high-temperature high-pressure gaseous refrigerant, the gaseous refrigerant flows to the condenser 2 and gradually condenses into a high-pressure liquid refrigerant, and the heat released by the condenser is carried away by the fan 8. The high-pressure liquid refrigerant after condensation passes through the throttling element 3 to reduce pressure and temperature and becomes a low-temperature low-pressure gas-liquid mixture. The gas-liquid mixed refrigerant enters the evaporator 4 and evaporates (boils) in the evaporator 4 to absorb heat. The refrigerant turns back into low-pressure gas and re-enters the compressor 1, and the cycle continues.

The vapor compression cooling unit and the forced convection cooling unit may have multiple combination modes in the invention, and invention uses the four modes in FIG. 1 to FIG. 4 as examples, but it is not limited thereto.

In an embodiment of the invention, as shown in FIG. 1 to FIG. 2, in the forced convection cooling unit, an inlet of the heat exchanger 6 is connected to the outlet of the liquid cooling plate 5, an outlet of the heat exchanger 6 is connected to an inlet of the second flow channel of the evaporator 4, and an outlet of the second flow channel of the evaporator 4 is connected to the inlet of the liquid cooling plate 5 by means of the water pump 7.

To be specific, the working process of the forced convection cooling unit in FIGS. 1 and 2 is: a high-temperature cooling liquid flows out of the liquid cooling plate and flows into the heat exchanger 6, is forcibly air-cooled through the fan 8, becomes a medium-temperature cooling liquid, flows through the second flow channel of the evaporator 4, undergoes convection heat exchange with the refrigerant in the first flow channel in the evaporator 4, and becomes a low-temperature cooling liquid. The low-temperature cooling liquid flows into the liquid cooling plate and undergoes convection heat exchange with the power module 100 and carries away the heat generated by the power module 100. The power for the cooling liquid circuit is provided by the water pump 7, and whether a water tank is installed is determined according to the circumstances. The energy cascade principle is utilized to the maximum extent, the effect of high-grade energy is fully utilized, the heat exchange efficiency is improved, and the costs are reduced in this approach.

In an embodiment of the invention, as shown in FIG. 3, in the forced convection cooling unit, the second flow channel is also connected to the outlet of the heat exchanger 6 through an electric regulating valve Q.

To be specific, referring to FIG. 3, the high-temperature cooling liquid flows out of the liquid cooling plate 5 and flows into the heat exchanger 6 and divides into two routes. The first route flows into the second flow channel of the evaporator 4, and the second route rejoins the first route at the outlet of the evaporator 4 to become one route. The flow distribution may be implemented through the electric regulating valve Q and other approaches. The combined cooling liquid flows into the liquid cooling plate 5 for convection heat exchange, so as to carry away the heat of the power module 100. The power for the forced convection cooling unit is provided by the water pump 7, and whether a water tank is installed is determined according to the circumstances. The effect of the high-grade energy is utilized to the maximum extent, pipe resistance is reduced according to the circumstances, and power consumption of the water pump is decreased in this approach.

According to an embodiment of the invention, as shown in FIG. 4, in the forced convection cooling unit, the outlet of the liquid cooling plate 5 is connected to the inlet of the second flow channel of the evaporator 4 by means of a first one-way valve Q1. The outlet of the second flow channel of the evaporator 4 is connected to the inlet of the liquid cooling plate 5 by means of the water pump 7, and the outlet of the second flow channel of the evaporator 4 is connected to the inlet of the heat exchanger 6. The outlet of the heat exchanger 6 is connected to the inlet of the second flow channel of the evaporator 4 by means of a second one-way valve Q2.

To be specific, as shown in FIG. 4, the cooling liquid flows out of the liquid cooling plate 5 and first divides into 2 routes for flowing into the heat exchanger 6 and the second flow channel of the evaporator 4. The flow distribution may be implemented through the electric regulating valve and other approaches. The 2 routes of cooling liquid flowing out then separately combine into one route for flowing into the liquid cooling plate 5 for convection heat exchange and carrying away the heat generated by the power module 100. The power for the forced convection cooling unit is provided by the water pump 7, and whether a water tank is installed is determined according to the circumstances. The effect of the high-grade energy is fully utilized, pipe resistance is reduced to the maximum extent, and power consumption of the water pump is decreased in this approach.

The cooling system may control the start-stop and frequency adjustment of the vapor compression cooling unit according to the operating conditions of the charging system. Under low operating conditions, the vapor compression cooling unit is turned off to reduce power consumption. Under high operating conditions, the vapor compression cooling unit is started, and frequency adjustment is made according to the circumstances to compensate for the insufficient cooling capacity of the forced air cooling system, so as to satisfy the cooling requirements of high-power charging. The start-stop of the liquid pump and the start-stop and adjustment of the cooling system may be controlled according to the start-stop of the charging system or the output signal of the temperature monitoring point.

In summary, according to the cooling system of the charging system of the embodiments of the invention, a liquid cooling approach is provided for charging piles. The cooling system is implemented in a combined form of forced convection and vapor compression. The cooling liquid is cooled through convection heat exchange in the evaporator by means of the forced convection cooling unit and the vapor compression cooling unit, so the energy cascade principle is utilized to the maximum extent, the effect of high-grade energy is fully utilized, the heat exchange efficiency is improved, and the costs are reduced. Through the phase change refrigeration mode of vapor compression, the cooling liquid temperature may be set to a lower temperature according to needs, so heat exchange efficiency is improved, and the heat dissipation needs of high-power charging are satisfied. The cooling system and the charging system only need to be connected through pipe connectors, so production, installation, and later maintenance may be easily performed, the high protective nature of the charging pile is ensured, contamination of the power module 100 by polluted air from the outside is avoided, and the service life of the power module 100 is thus prolonged. The vapor compression pipe and the cooling pipe are mutually independent with high reliability. The usage rate of the vapor compression unit may be reduced in a hybrid cooling system, so damage to the environment is lowered, and it is more environmentally friendly. The refrigerant flow of the cooling system may be infinitely adjusted according to the temperature changes of a detection temperature point of the charging system, so the operating condition changes can be responded quickly and energy-saving is thus achieved.

Based on the above cooling system of the charging system, the invention further provides a control method for the cooling system of the charging system.

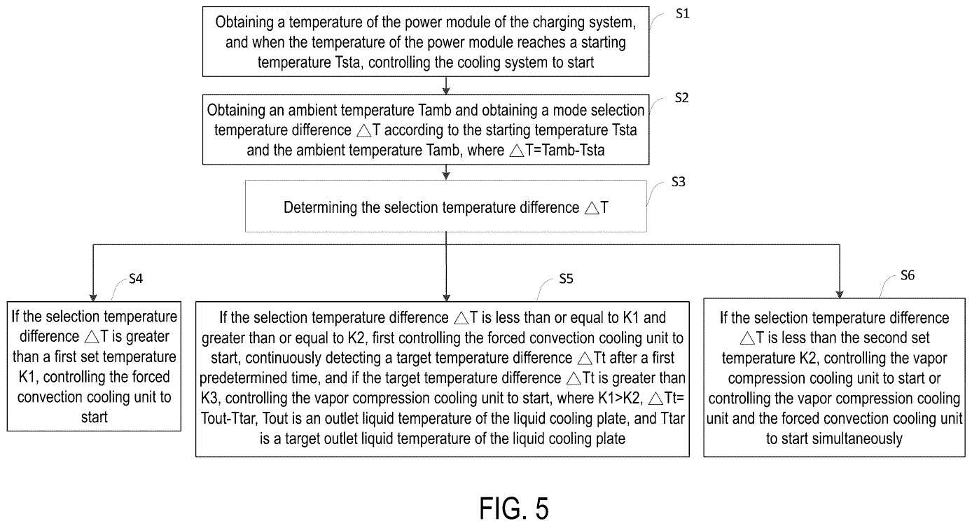

FIG. 5 is a flow chart of a control method for the cooling system of the charging system according to an embodiment of the invention. As shown in FIG. 5, the method includes the following steps:

In S1, a temperature of the power module of the charging system is obtained, and when the temperature of the power module reaches a starting temperature Tsta, the cooling system is controlled to start.

The starting temperature Tsta is set according to the specific conditions of the power module of the charging system.

In S2, an ambient temperature Tamb is obtained, and a mode selection temperature difference ΔT is obtained according to the starting temperature Tsta and the ambient temperature Tamb, where ΔT=Tamb-Tsta.

In S3, the selection temperature difference ΔT is determined.

In S4, if the selection temperature difference ΔT is greater than a first set temperature K1, the forced convection cooling unit to is controlled to start. K1 may be a temperature between 10 °C to 30 °C.

In S5, if the selection temperature difference ΔT is less than or equal to the first set temperature K1 and greater than or equal to a second set temperature K2, the forced convection cooling unit is controlled to start first, a target temperature difference ΔTt is continuously detect after a first predetermined time, and if the target temperature difference ΔTt is greater than a third set temperature K3, the vapor compression cooling unit is controlled to start, where K1>K2, ΔTt=Tout-Ttar, Tout is an outlet liquid temperature of the liquid cooling plate, and Ttar is a target outlet liquid temperature of the liquid cooling plate.

K2 may be a temperature between 0 to K1, K3 may be a temperature between 3 to 15, the first predetermined time may be 3-10 min.

In S6, if the selection temperature difference ΔT is less than the second set temperature K2, the vapor compression cooling unit is controlled to start, or the vapor compression cooling unit and the forced convection cooling unit are controlled to start simultaneously.

According to an embodiment of the invention, the control module may further include the following: After the forced convection cooling unit starts, a water pump flow rate and a fan rotation speed are adjusted according to a value and a trend of the target temperature difference ΔTt. After the vapor compression cooling unit starts, a frequency of the compressor is adjusted according to the value and the trend of the target temperature difference ΔTt, and the water pump flow rate and fan rotation speed are adjusted simultaneously.

To be specific, the adjustment of the compressor frequency, water pump flow rate, and fan rotation speed is positively correlated with the target temperature difference ΔTt. It may be determined according to the specific value of the target temperature difference ΔTt, or may be determined according to a temperature range to which the target temperature difference ΔTt belongs.

Control is mainly performed based on the outlet temperature of the liquid cooling plate in the above method, and other control methods including the control method based on the temperature of the power module and other control methods may also be used. The parameters can be adjusted accordingly according to the controlled object and the technical specifications of the power module.

It may be understood that the vapor compression cooling unit of the invention is an auxiliary cooling unit, which is started for auxiliary cooling when the forced convection cooling unit cannot achieve the required cooling effect.

In view of the foregoing, in the control method for the cooling system of the charging system according to the embodiments of the invention, the refrigerant flow of the cooling system may be infinitely adjusted according to the temperature changes of the detection temperature point of the charging system, so the operating condition changes can be responded quickly and energy-saving is thus achieved.

In the description of the invention, it should be understood the terms “first” and “second” are only used for differentiating and descriptive purposes and cannot be understood as indicating or implying relative importance or implicitly indicating the number of indicated technical features. Thus, the features defined with “first” and “second” may explicitly or implicitly include at least one of these features. In the description of the invention, “plurality” means at least two, such as two, three, etc., unless otherwise expressly and specifically defined.

In the invention, unless clearly specified and defined otherwise, the terms “installed”, “connected”, “connecting”, “fixed” and other terms should be understood in a broad sense, for instance, it can be a fixed connection, a detachable connection, or an integral connection, it can be a mechanical connection or an electrical connection, it can be a direct connection or an indirect connection through an intermediate medium, and it can be an internal communication between two components or an interaction relationship between two components, unless clearly defined otherwise. For a person having ordinary skill in the art, the specific meaning of the above-mentioned terms in the present invention can be understood according to specific circumstances.

In the description of the specification, descriptions with reference to the terms such as “one embodiment”, “some embodiments”, “examples”, “specific examples”, or “some examples” etc. means that the specific features, structures, materials, or characteristics described in combination with the embodiment(s) or example(s) are included in at least one embodiment or example of the invention. In the specification, the schematic representation of the above-mentioned terms does not necessarily refer to the same embodiment or example. Further, the described specific features, structures, materials, or characteristics may be combined in any one or more embodiments or examples in a suitable manner. Besides, a person having ordinary skill in the art may reincorporate and combine different embodiments or examples and features of different embodiments or examples described in the specification without conflicting with each other.

Any process or method descriptions in the flow chart or otherwise described herein may be understood to represent modules, segments, or portions of code including one or more executable instructions for implementing custom logical functions or steps of the process. Further, the scope of the preferred embodiments of the invention includes alternative implementations in which functions may be performed out of the order shown or discussed, including substantially concurrent or in reverse order, depending upon the functions involved, which should be recognized by a person having ordinary skill in the art.

The logic and/or steps represented in the flow chart or otherwise described herein, such as a sequenced list of executable instructions, which are considered to be used to implement logical functions, may be embodied in any computer readable medium for use by or in together with, an instruction execution system, apparatus, or device (e.g., a computer-based system, a system including a processor, or other systems that can fetch and execute instructions from an instruction execution system, device, or apparatus). In the specification, the “computer-readable medium” may be any means that can contain, store, communicate, propagate, or transport the program for use by or together with an instruction execution system, device, or apparatus. More specific examples (non-exhaustive list) of the computer-readable medium include the following: an electrical connection portion (electronic device) with one or more wires, a portable computer disk case (magnetic device), a random access memory (RAM), a read-only memory (ROM), an erasable programmable read-only memory (EPROM or flash memory), a fiber optic device, and a portable optical disk ROM (CD-ROM). Besides, the computer-readable medium may even be paper or other suitable medium on which the program may be printed, as the paper or other medium may be scanned, for example, optically. The program is then obtained electronically by editing, interpreting or, if necessary, processing in another suitable manner, and the program is then stored in a computer memory.

It should be understood that various parts of the invention may be implemented by hardware, software, firmware, or a combination thereof. In the embodiments described above, various steps or methods may be implemented by software or firmware stored in memory and executed by a suitable instruction execution system. For instance, if implemented in hardware, as in another embodiment, it can be implemented by any one or a combination of the following techniques known in the art: a discrete logic circuit with logic gates for implementing logic functions on data signals, an application specific integrated circuit with appropriate combinational logic gates, a programmable gate array (PGA), a field programmable gate array (FPGA), etc.

A person having ordinary skill in the art can understand that all or part of the steps carried out in the method of the above embodiments can be implemented by instructing related hardware through a program. The program can be stored in a computer-readable storage medium, and when the program is executed, it includes one of the steps of the method embodiments or a combination thereof.

In addition, in the embodiments of the invention, each functional unit may be integrated into one processing module, or each unit may exist alone physically, or two or more units may be integrated into one module. The integrated module may be implemented in the form of hardware or in the form of a software functional module. If the integrated module is implemented in the form of a software functional module and sold or used as an independent product, it may also be stored in a computer-readable storage medium.

Although the embodiments of the invention have been shown and described above, it can be understood that the above-mentioned embodiments are exemplary and should not be construed as limiting the invention. A person having ordinary skill in the art may make changes, corrections, substitutions, and modifications to the abovementioned embodiments within the scope of the invention.

1. cooling system of a charging system, comprising:
a vapor compression cooling unit, comprising: a compressor, a condenser, a throttling element, and an evaporator which are sequentially connected by means of a vapor compression pipe, wherein the vapor compression cooling unit uses a refrigerant for circulation;
a forced convection cooling unit, comprising: a liquid cooling plate, a heat exchanger, the evaporator, and a water pump which are connected by means of a cooling pipe, wherein the forced convection cooling unit uses a cooling liquid for circulation, and the liquid cooling plate is tightly attached to a power module of the charging system,
wherein the condenser of the vapor compression cooling unit is arranged close to the heat exchanger of the vapor compression cooling unit, the vapor compression cooling unit and the forced convection cooling unit further comprise: a fan, wherein the fan is arranged directly opposite to the heat exchanger and the condenser, the fan is used for air cooling the condenser and the heat exchanger, the vapor compression cooling unit and the forced convection cooling unit share one evaporator, the evaporator comprises a first flow channel and a second flow channel, the vapor compression pipe communicates with the first flow channel, the cooling pipe communicates with the second flow channel, and the evaporator is used for evaporating a refrigerant flowing out from the condenser to perform convective heat exchange on the cooling liquid in the second flow channel and the refrigerant in the first flow channel.

2. The cooling system of the charging system according to claim 1, wherein in the forced convection cooling unit, an inlet of the heat exchanger is connected to an outlet of the liquid cooling plate, an outlet of the heat exchanger is connected to an inlet of the second flow channel of the evaporator, and an outlet of the second flow channel of the evaporator is connected to an inlet of the liquid cooling plate by means of the water pump.

3. The cooling system of the charging system according to claim 2, wherein in the forced convection cooling unit, the second flow channel is also connected to the outlet of the heat exchanger through an electric regulating valve.

4. The cooling system of the charging system according to claim 1, wherein in the forced convection cooling unit, an outlet of the liquid cooling plate is connected to an inlet of the second flow channel of the evaporator through a first one-way valve, an outlet of the second flow channel of the evaporator is connected to an inlet of the liquid cooling plate by means of the water pump, the outlet of the second flow channel of the evaporator is connected to an inlet of the heat exchanger, and an outlet of the heat exchanger is connected to the inlet of the second flow channel of the evaporator by means of a second one-way valve.

5. The cooling system of the charging system according to claim 1, wherein the vapor compression pipe comprises a copper tube.

6. A control method for the cooling system of the charging system according to claim 1, comprising the following steps:
obtaining a temperature of the power module of the charging system, and when the temperature of the power module reaches a starting temperature Tsta, controlling the cooling system to start;
obtaining an ambient temperature Tamb and obtaining a mode selection temperature difference ΔT according to the starting temperature Tsta and the ambient temperature Tamb, wherein ΔT=Tamb-Tsta;
determining the selection temperature difference ΔT, comprising:
if the selection temperature difference ΔT is greater than a first set temperature K1, controlling the forced convection cooling unit to start;
if the selection temperature difference ΔT is less than or equal to the first set temperature K1 and greater than or equal to a second set temperature K2, first controlling the forced convection cooling unit to start, continuously detecting a target temperature difference ΔTt after a first predetermined time, and if the target temperature difference ΔTt is greater than a third set temperature K3, controlling the vapor compression cooling unit to start, wherein K1>K2, ΔTt=Tout-Ttar, Tout is an outlet liquid temperature of the liquid cooling plate, and Ttar is a target outlet liquid temperature of the liquid cooling plate; and
if the selection temperature difference ΔT is less than the second set temperature K2, controlling the vapor compression cooling unit to start or controlling the vapor compression cooling unit and the forced convection cooling unit to start simultaneously.

7. The control method for the cooling system of the charging system according to claim 6, further comprising:
after the forced convection cooling unit starts, adjusting a water pump flow rate and a fan rotation speed according to a value and a trend of the target temperature difference ΔTt; and
after the vapor compression cooling unit starts, adjusting a frequency of the compressor according to the value and the trend of the target temperature difference ΔTt and adjusting the water pump flow rate and fan rotation speed simultaneously.
